(19) United States
(12) Patent Application Publication
(10) Pub. No.: US 2010/0201899 A1
(43) Pub. Date: Aug. 12, 2010

(54) DISCHARGE DETECTION CIRCUIT, LIQUID CRYSTAL DRIVING DEVICE, LIQUID CRYSTAL DISPLAY DEVICE, AND DISCHARGE DETECTION METHOD

(75) Inventor: Ken Yamamoto, Tokyo (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/700,109

(22) Filed: Feb. 4, 2010

(30) Foreign Application Priority Data
Feb. 6, 2009 (JP) 2009-25779

(51) Int. Cl. G02F 1/1333; G01R 31/00

(52) U.S. Cl. 349/40; 324/537

(57) ABSTRACT

A discharge detection circuit has an electrostatic discharge detector that has at least one of a first detector detecting a positive voltage surge and outputting a first detection signal and a second detector detecting a negative voltage surge and outputting a second detection signal, and outputs a detection signal indicating whether the surge is generated, based on at least one of the first detection signal and the second detection signal, and an external output terminal that outputs the detection signal.

### CROSS REFERENCE TO RELATED APPLICATION

This application is based upon and claims benefit of priority from the Japanese Patent Application No. 2009-25779, filed on Feb. 6, 2009, the entire contents of which are incorporated herein by reference.

### BACKGROUND OF THE INVENTION

The present invention relates to a discharge detection circuit, a liquid crystal driving device, a liquid crystal display device, and a discharge detection method.

When a surge is generated due to electrostatic discharge from the outside, even though a semiconductor device is not destroyed, the semiconductor device may perform an abnormal operation due to rewriting of data of an internal register, and the abnormal operation cannot be detected from an external device.

For example, in a driving device of a liquid crystal display device, setting information of the size of a display screen, display voltage data, and a count value of a display controlling counter that are stored in a liquid crystal display controlling register are rewritten due to the surge caused by the electrostatic discharge. As a result, even though display synchronization is not taken and abnormality is generated in the display screen, a control system cannot detect the generation of the abnormality.

As a device that detects damage by the electrostatic discharge, Japanese Patent Application Laid-Open No. 10-12691 suggests a discharge detection device that compares a pattern of a discharge detection signal detected through an antenna detecting electromagnetic waves of all discharges including electrostatic discharge and waveform patterns of electromagnetic waves of static electricity discharge stored in advance, and issues an alarm when it is determined that the patterns are matched as a comparison result.

However, in the discharge detection device, since the antenna detecting the electromagnetic waves and a storage unit storing the waveform patterns of the electromagnetic waves of the static electricity discharge need to be provided, a manufacturing cost thereof increases and an interface with another device becomes difficult.

### SUMMARY OF THE INVENTION

According to one aspect of the present invention, there is provided a discharge detection circuit, comprising:

an electrostatic discharge detector that has at least one of a first detector detecting a positive voltage surge and outputting a first detection signal and a second detector detecting a negative voltage surge and outputting a second detection signal, and outputs a detection signal indicating whether the surge is generated, based on at least one of the first detection signal and the second detection signal; and

an external output terminal that outputs the detection signal.

According to one aspect of the present invention, there is provided a liquid crystal driving device that drives a liquid crystal display panel, comprising:

the discharge detection circuit that detects a surge voltage according to electrostatic discharge generated in the liquid crystal driving device.

According to one aspect of the present invention, there is provided a liquid crystal display device, comprising:

a liquid crystal display panel; and

the liquid crystal driving device that drives the liquid crystal display panel.

According to one aspect of the present invention, there is provided a discharge detection method in which an external device detects discharge using an electrostatic discharge detector detecting a positive voltage surge or a negative voltage surge and outputting a detection signal indicating whether the surge is generated, the discharge detection method comprising:

allowing the external device to reset the electrostatic discharge detector;

allowing the electrostatic discharge detector to detect the surge generated in a power line according to reception of electrostatic discharge and output the detection signal; and

allowing the external device to reset a value of internal setting to a predetermined value, based on the detection signal.

### BRIEF DESCRIPTION OF THE DRAWINGS

FIG. 1 is a diagram illustrating the schematic configuration of a discharge detection circuit according to an embodiment of the present invention;

FIG. 2 is a flowchart illustrating a discharge detection method using the discharge detection circuit according to the embodiment;

FIG. 3 is a diagram illustrating an example of the configuration of an electrostatic discharge detector;

FIG. 4 is a diagram illustrating an example of the configuration of an electrostatic discharge detector;

FIG. 5 is a diagram illustrating the schematic configuration of a liquid crystal driving device comprising the discharge detection circuit; and

FIG. 6 is a diagram illustrating the schematic configuration of a discharge detection circuit according to a variation.

### DETAILED DESCRIPTION OF THE INVENTION

Hereafter, an embodiment of the present invention will be described with reference to the drawings.

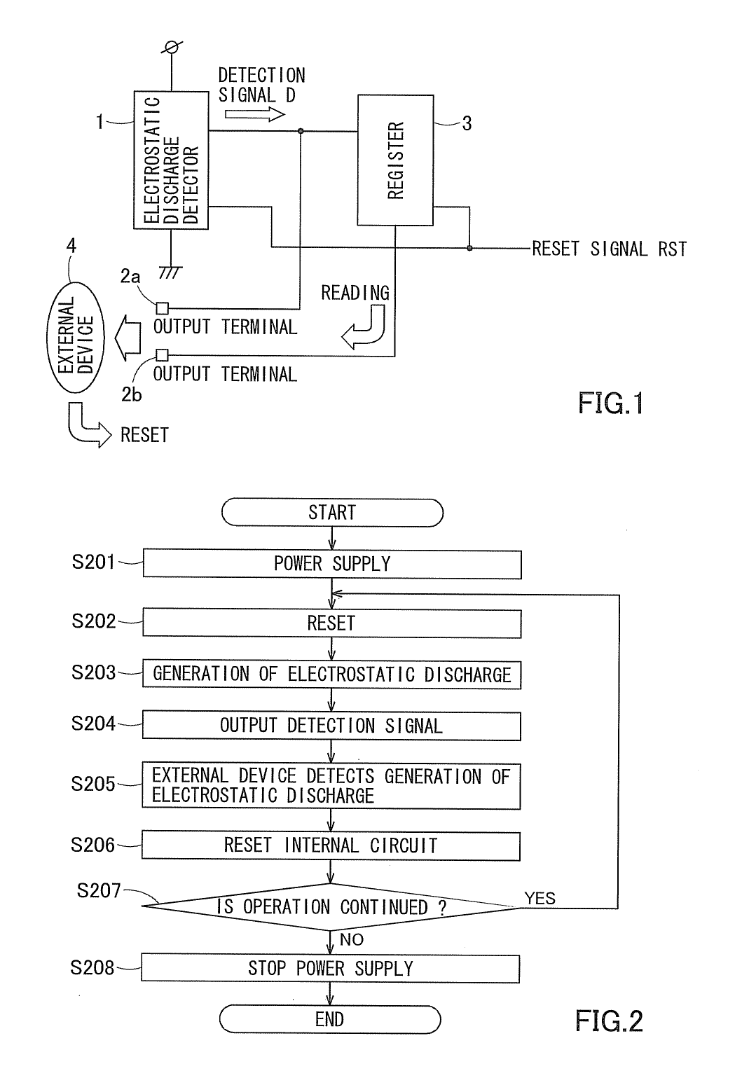

FIG. 1 illustrates the schematic configuration of a discharge detection circuit according to an embodiment of the present invention. The discharge detection circuit includes an electrostatic discharge detector 1, output terminals 2a and 2b, and a register 3 and is provided in a TFT liquid crystal driver.

The electrostatic discharge detector 1 detects a rapid voltage change (surge) generated in a power line, when the discharge detection circuit (device including the discharge detection circuit) receives electrostatic discharge, and outputs a detection signal D indicating the reception of the electrostatic discharge. The detection signal D is output to the register 3. In the register 3, a held value is changed by the detection signal D.

The register 3 is connected to the output terminal 2b through a data bus. An external device 4 reads the value, which is held in the register 3, from the output terminal 2b, thereby detecting whether the detection signal D is output, that is, the electrostatic discharge exists.

The detection signal D is output from the output terminal 2a to the external device 4. That is, the discharge detection circuit (electrostatic discharge detector 1) can notify the external device 4 that the electrostatic discharge is received.

The external device 4 detects the generation of the electrostatic discharge, based on the detection signal D output from the output terminal 2a or held data of the register 3 read from the output terminal 2b. If the electrostatic discharge is generated, internal setting of the device that includes the discharge detection circuit may be unintentionally changed. For this reason, if the external device 4 detects the generation of the electrostatic discharge, the external device 4 resets the value of the internal setting to a correct value.

If the external device 4 detects the generation of the electrostatic discharge, the external device 4 outputs a reset signal RST to the electrostatic discharge detector 1 and the resister 3. The electrostatic discharge detector 1 and the register 3 are reset to an internal state before the detection of the electrostatic discharge, based on the reset signal RST, and the electrostatic discharge detector 1 returns to a state where the electrostatic discharge can be detected. The external device 4 outputs the reset signal RST, even when power is supplied to the device including the discharge detection circuit.

FIG. 2 is a flowchart illustrating the operation of the discharge detection circuit and the external device 4 when electrostatic discharge is generated.

First, the external device 4 supplies power to the device including the discharge detection circuit (S201).

The external device 4 outputs the reset signal RST and the electrostatic discharge detector 1 enters in a state where the electrostatic discharge can be detected (S202).

The device that includes the discharge detection circuit receives the electrostatic discharge and a surge is generated in the power line (S203).

The electrostatic discharge detector 1 detects the generation of the electrostatic discharge, and outputs the detection signal D (S204). The held value of the register 3 is rewritten by the detection signal D output from the electrostatic discharge detector 1.

The external device 4 detects the generation of the electrostatic discharge, based on the detection signal D output from the output terminal 2a or the value of the register 3 read through the output terminal 2b (S205).

The external device 4 resets the value of the internal setting of the device including the discharge detection circuit to a correct value (S206).

The external device 4 determines whether or not to continuously perform the operation of the device including the discharge detection circuit (S207). When it is determined that the operation is continuously performed, the external device 4 returns to step 202. When it is determined that the operation is stopped, the external device 4 proceeds to step 208.

The external device 4 stops supply of the power to the device including the discharge detection circuit (S208).

The external device 4 detects the generation of the electrostatic discharge from the detection signal D output from the output terminal 2a or the value of the register 3 read through the output terminal 2b, and resets the internal setting of the device including the discharge detection circuit. As a result, the external device 4 can prevent the abnormal operation from being generated.

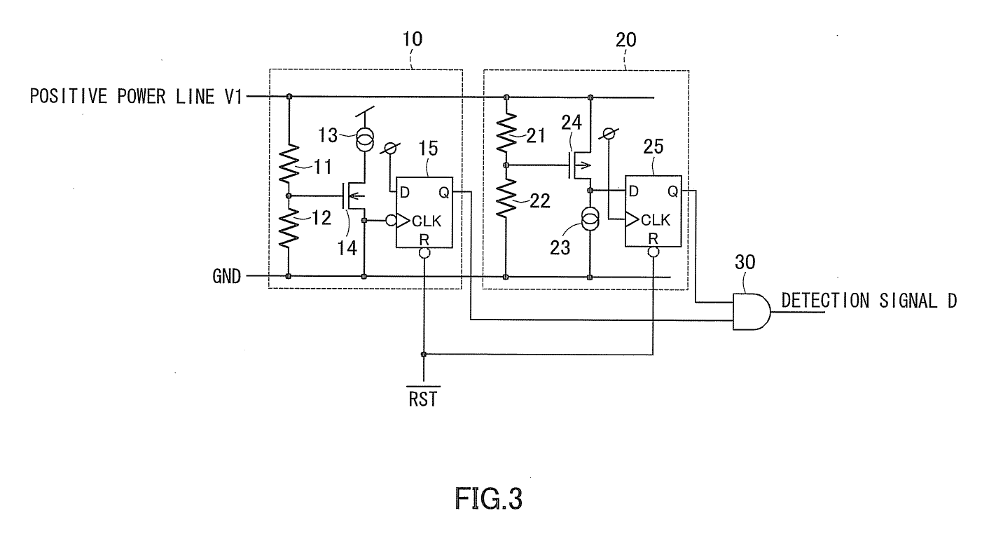

FIG. 3 illustrates an example of the configuration of the electrostatic discharge detector 1. The electrostatic discharge detector 1 has a plus surge detector 10 that detects a plus surge generated in a positive power line V1 due to electrostatic discharge, a minus surge detector 20 that detects a minus surge, and an OR gate 30. The OR gate 30 receives an output of the plus surge detector 10 and an output of the minus surge detector 20, and outputs the detection signal D.

The plus surge detector 10 has resistors 11 and 12, a constant current circuit 13, an NMOS transistor 14, and a flip-flop 15.

The resistors 11 and 12 are connected in series between the positive power line V1 and a ground line GND, and a gate of the NMOS transistor 14 is connected to a connection point of the resistors 11 and 12. One of a source and a drain of the NMOS transistor 14 is connected to the constant current circuit 13 and the other is connected to the ground line GND and a clock terminal of the flip-flop 15. An output of the flip-flop 15 is input to the OR gate 30.

The flip-flop 15 is reset by the reset signal RST. For example, a held value of the flip-flop 15 becomes 0 by the reset.

A resistance value of the resistor 11 is larger than a resistance value of the resistor 12. The NMOS transistor 14 is turned off in a normal state (state where a surge is not generated), and the value that is held and output by the flip-flop 15 becomes 0.

The minus surge detector 20 has resistors 21 and 22, a constant current circuit 23, a PMOS transistor 24, and a flip-flop 25.

The resistors 21 and 22 are connected in series between the positive power line V1 and the ground line GND, and a gate of the PMOS transistor 24 is connected to a connection point of the resistors 21 and 22. One of a source and a drain of the PMOS transistor 24 is connected to the positive power line V1 and the other is connected to the constant current circuit 23 and a data input terminal of the flip-flop 25. An output of the flip-flop 25 is input to the OR gate 30.

The flip-flop 25 is reset by the reset signal RST. For example, a held value of the flip-flop 25 becomes 0 by the reset.

The PMOS transistor 24 is turned off in a normal state (state where a surge is not generated), and the value that is held and output by the flip-flop 25 becomes 0.

If a plus surge is generated in the positive power line V1, a gate potential of the NMOS transistor 14 increases and the NMOS transistor 14 is turned on. If the NMOS transistor 14 is turned on, a constant current flows from the constant current circuit 13 to the ground line GND and a clock is input to the flip-flop 15. As a result, the value that is held and output by the flip-flop 15 becomes 1.

Accordingly, a value of the output (detection signal D) of the OR gate 30 becomes 1, and the discharge is detected.

Meanwhile, if a minus surge is generated, a gate potential of the PMOS transistor 24 decreases and the PMOS transistor 24 is turned on. If the PMOS transistor 24 is turned on, a constant current flows from the constant power line V1 to the ground line GND through the PMOS transistor 24 and the constant current circuit 23. As a result, the value that is held and output by the flip-flop 25 becomes 1.

Accordingly, the value of the output (detection signal D) of the OR gate 30 becomes 1, and the discharge is detected.

The external device 4 detects the detection signal D output from the OR gate 30 through the output terminal 2a or reads the held data of the register 3 rewritten by the detection signal D output from the OR gate 30 through the output terminal 2b, thereby detecting the generation of the electrostatic discharge.

As such, if the discharge detection circuit according to the embodiment is used, the electrostatic discharge can be detected with the simple configuration. The discharge detection circuit according to the embodiment can output the detection signal D from the output terminal 2a and read the data of the register 3 rewritten by the detection signal D from the output terminal 2b. Therefore, the discharge detection circuit can easily interface with another device (external device 4).

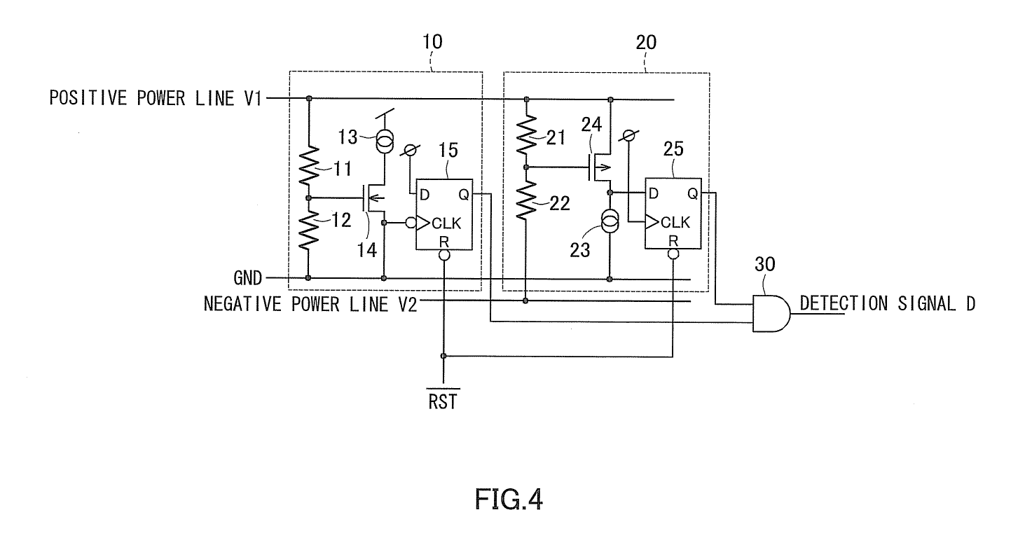

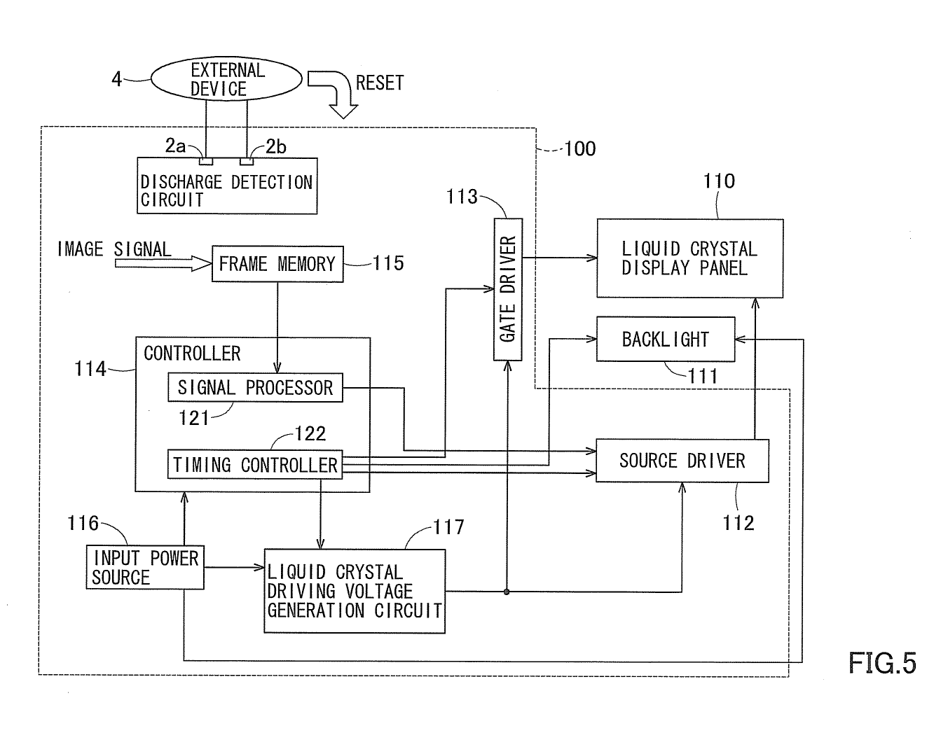

In the electrostatic discharge detector 1 illustrated in FIG. 3, a negative power line is not provided. However, when the negative power line is provided, the configuration illustrated in FIG. 4 is used. The configuration of FIG. 4 is the same as the configuration of FIG. 3, except that one end of the resistor 22 is connected to a negative power line V2.

By this configuration, discharge (surge) that is generated in the negative power line V2 can be detected.

The discharge detection circuit according to the embodiment is provided in a driving device 100 driving a liquid crystal display panel 110 and/or a backlight 111 illustrated in FIG. 5. In the liquid crystal display panel 110, signal lines and scanning lines are disposed in a matrix, and liquid crystal display elements are provided at intersections thereof. The backlight 111 is disposed on a back surface of the liquid crystal display panel 110, and illuminates the liquid crystal display panel 110 with plural cold-cathode tubes.

The driving device 100 includes a source driver 112, a gate driver 113, a controller 114, a frame memory 115, an input power source 116, and a liquid crystal driving voltage generation circuit 117.

The input power source 116 supplies power to the backlight 111, the controller 114, and the liquid crystal driving voltage generation circuit 117. The liquid crystal driving voltage generation circuit 117 adjusts a voltage that is supplied to the source driver 112 and the gate driver 113, according to timing when display data is displayed on the liquid crystal display panel 110.

The gate driver 113 supplies a gate signal to the scanning lines of the liquid crystal display panel 110, and the source driver 112 supplies a voltage corresponding to a display signal to the signal lines of the liquid crystal display panel 110.

The frame memory 115 stores an input image signal and outputs the image signal.

The controller 114 has a signal processor 121 and a timing controller 122. The signal processor 121 receives the image signal (image data) output from the frame memory 115, and outputs a display signal corresponding to the image signal to the source driver 112. The timing controller 122 outputs a timing control signal to the backlight 111, the source driver 112, the gate driver 113, and the liquid crystal driving voltage generation circuit 117.

The backlight 111 illuminates the liquid crystal display panel 110 during only a period where the liquid crystal display elements of the liquid crystal display panel 110 respond to the display signal, based on the timing control signal.

In the driving device 100, registers or counters (not illustrated) are provided. If the electrostatic discharge is generated, the data is rewritten, and abnormality may be generated in a display image of the liquid crystal display panel 110. Since the discharge detection circuit according to the embodiment is provided in the driving device 100, the external device 4 can detect that the electrostatic discharge is generated in the driving device 100.

If the external device 4 detects that the electrostatic discharge is generated in the driving device 100, the external device 4 resets a value of the register or the counter in the driving device 100 to a correct value. For this reason, the abnormality of the display image that is generated due to the electrostatic discharge can be quickly removed.

The discharge detection circuit according to the embodiment can be applied to various devices where it is required to externally detect whether the electrostatic discharge is generated as well as a liquid crystal display device.

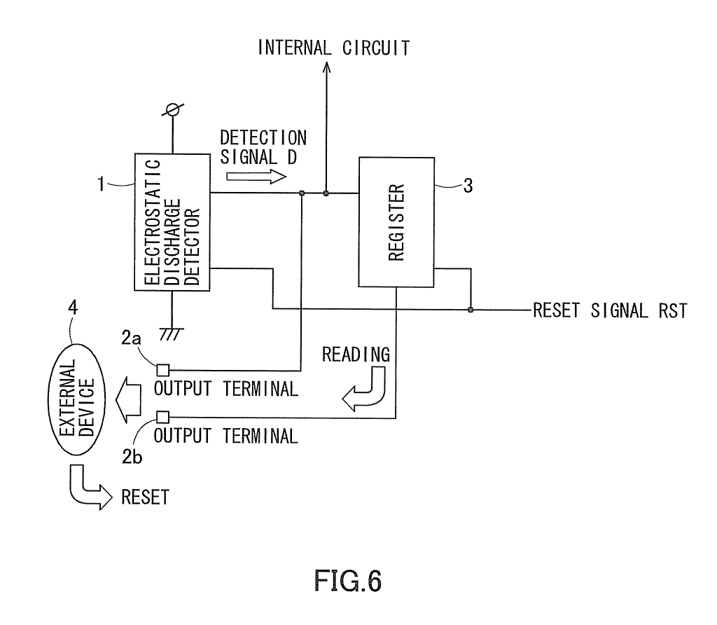

As illustrated in FIG. 6, the electrostatic discharge detector 1 may output the detection signal D to the internal circuit, and the internal circuit may be reset by the device including the electrostatic discharge detector 1, not the external device.

In the above-described embodiment, the external device 4 may output the reset signal RST. However, the internal circuit may generate and output the reset signal.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A discharge detection circuit, comprising:
an electrostatic discharge detector that has at least one of a first detector detecting a positive voltage surge and outputting a first detection signal and a second detector detecting a negative voltage surge and outputting a second detection signal, and outputs a detection signal indicating whether the surge is generated, based on at least one of the first detection signal and the second detection signal; and
an external output terminal that outputs the detection signal.

2. The discharge detection circuit according to claim 1, further comprising:
a register of which a value is rewritten by the detection signal; and
a second external output terminal that is connected to the register through a data bus.

3. The discharge detection circuit according to claim 2,
wherein the electrostatic discharge detector and the register receive a reset signal, and are reset based on the reset signal.

4. The discharge detection circuit according to claim 1,
wherein the first detector includes
first and second resistors that are connected in series between a power line and a ground line,
an NMOS transistor of which a gate electrode is connected to a connection point of the first and second resistors and one of a source and a drain is connected to the ground line,
a first constant current circuit that is connected to the other of the source and the drain of the NMOS transistor, and
a first flip-flop of which a data input terminal receives a first signal, a clock terminal is connected to one of the source and the drain of the NMOS transistor, and a data output terminal outputs the first detection signal,
wherein the second detector includes
third and fourth resistors that are connected in series between the power line and the ground line,
a PMOS transistor of which a gate electrode is connected to a connection point of the third and fourth resistors and one of a source and a drain is connected to the power line,
a second constant current circuit that is connected between the other of the source and the drain of the PMOS transistor and the ground line, and
a second flip-flop of which a clock terminal receives the first signal, a data input terminal is connected to the other of the source and the drain of the PMOS transistor, and a data output terminal outputs the second detection signal, and
wherein the electrostatic discharge detector has an OR gate that receives the first and second detection signals and outputs the detection signal.

5. The discharge detection circuit according to claim 1,
wherein the first detector includes
first and second resistors that are connected in series between a positive power line and a ground line,
an NMOS transistor of which a gate electrode is connected to a connection point of the first and second resistors and one of a source and a drain is connected to the ground line,
a first constant current circuit that is connected to the other of the source and the drain of the NMOS transistor, and
a first flip-flop of which a data input terminal receives a first signal, a clock terminal is connected to one of the source and the drain of the NMOS transistor, and a data output terminal outputs the first detection signal,
wherein the second detector includes
third and fourth resistors that are connected in series between the positive power line and a negative power line,
a PMOS transistor of which a gate electrode is connected to a connection point of the third and fourth resistors and one of a source and a drain is connected to the positive power line,
a second constant current circuit that is connected between the other of the source and the drain of the PMOS transistor and the ground line, and
a second flip-flop of which a clock terminal receives the first signal, a data input terminal is connected to the other of the source and the drain of the PMOS transistor, and a data output terminal outputs the second detection signal, and
wherein the electrostatic discharge detector has an OR gate that receives the first and second detection signals and outputs the detection signal.

6. The discharge detection circuit according to claim 1, further comprising:
an external device that receives the detection signal output from the external output terminal.

7. A liquid crystal driving device that drives a liquid crystal display panel, comprising:
the discharge detection circuit according to claim 1 that detects a surge voltage according to electrostatic discharge generated in the liquid crystal driving device.

8. The liquid crystal driving device according to claim 7,
wherein a predetermined value is set to a register and/or a counter provided in the liquid crystal driving device, based on an output of the detection signal from the discharge detection circuit.

9. A liquid crystal display device, comprising:
a liquid crystal display panel; and
the liquid crystal driving device according to claim 7 that drives the liquid crystal display panel.

10. The liquid crystal display device according to claim 9, further comprising:
a backlight that illuminates the liquid crystal display panel.

11. A discharge detection method in which an external device detects discharge using an electrostatic discharge detector detecting a positive voltage surge or a negative voltage surge and outputting a detection signal indicating whether the surge is generated, the discharge detection method comprising:
allowing the external device to reset the electrostatic discharge detector;
allowing the electrostatic discharge detector to detect the surge generated in a power line according to reception of electrostatic discharge and output the detection signal; and
allowing the external device to reset a value of internal setting to a predetermined value, based on the detection signal.
